(19) United States
(12) Patent Application Publication
(10) Pub. No.: US 2025/0309604 A1
(43) Pub. Date: Oct. 2, 2025

(54) TIME IMPARTING METHOD AND LASER APPARATUS

(71) Applicant: Gigaphoton Inc., Oyama-shi (JP)

(72) Inventors: Yutaka IGARASHI, Oyama-shi (JP); Yusuke FUJII, Oyama-shi (JP)

(73) Assignee: Gigaphoton Inc., Oyama-shi (JP)

(21) Appl. No.: 19/232,668

(22) Filed: Jun. 9, 2025

Related U.S. Application Data
(63) Continuation of application No. PCT/JP2023/001700, filed on Jan. 20, 2023.

(51) Int. Cl. H01S 3/097; G03F 7/00; H01S 3/225

(52) U.S. Cl. CPC H01S 3/09702; G03F 7/70025; G03F 7/70041; G03F 7/7055; H01S 3/225

(57) ABSTRACT

A time imparting method for imparting a time to two or more pieces of pulse data of a laser apparatus that burst-oscillates a pulse laser beam, includes causing a first processor including a real-time system to receive a first light emission trigger signal from a laser irradiation device and to measure a time interval between a previously received second light emission trigger signal and the first light emission trigger signal in the real-time system, and causing a second processor to receive the time interval from the first processor, and when the time interval is smaller than a set value, to impart a time obtained by adding the time interval to a time imparted to pulse data of a pulse laser beam corresponding to the second light emission trigger signal, to pulse data of a pulse laser beam corresponding to the first light emission trigger signal.

### CROSS-REFERENCE TO RELATED APPLICATIONS

The present application is a continuation application of International Application No. PCT/JP2023/001700, filed on Jan. 20, 2023, the entire contents of which are hereby incorporated by reference.

### BACKGROUND

### 1. Technical Field

The present disclosure relates to a time imparting method and a laser apparatus.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248 nm and an ArF excimer laser apparatus that outputs a laser beam having a wavelength of about 193 nm are used.

Spectral linewidths of spontaneous oscillation beams of the KrF excimer laser apparatus and the ArF excimer laser apparatus are as wide as from 350 pm to 400 pm. Therefore, when a projection lens is formed of a material that transmits ultraviolet light such as KrF and ArF laser beams, chromatic aberration may occur. As a result, the resolution may decrease. Thus, the spectral linewidth of the laser beam output from the gas laser apparatus needs to be narrowed to an extent that the chromatic aberration is ignorable. Therefore, in a laser resonator of the gas laser apparatus, a line narrowing module (LNM) including a line narrowing element (such as etalon or grating) may be provided in order to narrow the spectral linewidth. Hereinafter, a gas laser apparatus with a narrowed spectral linewidth is referred to as a line narrowing gas laser apparatus.

### LIST OF DOCUMENTS

### Patent Documents

Patent Document 1: Japanese Unexamined Patent Application Publication No. 2021-124966

### SUMMARY

A time imparting method according to one aspect of the present disclosure is for imparting a time to two or more pieces of pulse data of a laser apparatus that burst-oscillates a pulse laser beam. The time imparting method includes causing a first processor including a real-time system to receive a first light emission trigger signal from a laser irradiation device and to measure a time interval between a second light emission trigger signal received immediately before the first light emission trigger signal and the first light emission trigger signal in the real-time system, and causing a second processor to receive the time interval from the first processor, and when the time interval is smaller than a set value, to impart a time obtained by adding the time interval to a time imparted to pulse data of a pulse laser beam corresponding to the second light emission trigger signal, to pulse data of a pulse laser beam corresponding to the first light emission trigger signal.

A time imparting method according to another aspect of the present disclosure is for imparting a time to two or more pieces of pulse data of a laser apparatus that burst-oscillates a pulse laser beam. The time imparting method includes causing a first processor including a real-time system to receive a first light emission trigger signal from a laser irradiation device and to measure a time interval between a second light emission trigger signal received immediately before the first light emission trigger signal and the first light emission trigger signal in the real-time system, and causing a second processor to receive the time interval from the first processor, and when a time imparting signal is not received from the laser irradiation device, to impart a time obtained by adding the time interval to a time of pulse data of a pulse laser beam corresponding to the second light emission trigger signal, to pulse data of a pulse laser beam corresponding to the first light emission trigger signal.

A laser apparatus according to another aspect of the present disclosure outputs a pulse laser beam in response to a light emission trigger signal received from a laser irradiation device, and includes a first processor and a second processor. The first processor includes a real-time system and is configured to receive a first light emission trigger signal from the laser irradiation device and to measure a time interval between a second light emission trigger signal received immediately before the first light emission trigger signal and the first light emission trigger signal in the real-time system. The second processor is configured to receive the time interval from the first processor and, when the time interval is smaller than a set value, to impart a time obtained by adding the time interval to a time of pulse data of a pulse laser beam corresponding to the second light emission trigger signal, to pulse data of a pulse laser beam corresponding to the first light emission trigger signal.

### BRIEF DESCRIPTION OF THE DRAWINGS

Some embodiments of the present disclosure will be described below, by way of example only, with reference to the accompanying drawings.

FIG. 1 schematically illustrates a configuration of a laser apparatus according to a comparative example.

FIG. 2 illustrates an example of burst oscillation by a laser apparatus.

FIG. 3 is a flowchart illustrating an example of a processing procedure of a data collection processor according to the comparative example.

FIG. 4 is a table illustrating an example of pulse data received by the data collection processor.

FIG. 5 is a table illustrating an example of pulse data stored by the data collection processor.

FIG. 6 is a table illustrating an example of burst data.

FIG. 7 is a timing chart of transmission and reception of pulse data in the laser apparatus according to the comparative example.

FIG. 8 is a graph illustrating an oscillation start time of each of bursts No. 470 to 490.

FIG. 9 is a timing chart of transmission and reception of pulse data in a laser apparatus according to Embodiment 1.

FIG. 10 is a table illustrating an example of pulse data received by a data collection processor according to Embodiment 1.

FIG. 11 is a flowchart illustrating an example of a processing procedure of the data collection processor according to Embodiment 1.

FIG. 12 is a graph illustrating an oscillation start time of each of bursts No. 470 to 490 in the laser apparatus according to Embodiment 1.

FIG. 13 schematically illustrates a configuration of a laser apparatus according to Embodiment 2.

FIG. 14 is a timing chart of transmission and reception of pulse data in the laser apparatus according to Embodiment 2.

FIG. 15 is a flowchart illustrating an example of a processing procedure of a data collection processor according to Embodiment 2.

### DESCRIPTION OF EMBODIMENTS

### <Contents>

1. Terms
2. Description of Laser Apparatus According to Comparative Example
   2.1 Configuration
   2.2 Operation
   2.3 Problem
3. Embodiment 1
   3.1 Configuration
   3.2 Operation
   3.3 Effect and Advantage
4. Embodiment 2
   4.1 Configuration
   4.2 Operation
   4.3 Effect and Advantage
5. Others

Hereinafter, embodiments of the present disclosure will be described in detail with reference to the drawings. The embodiments described below show some examples of the present disclosure and do not limit contents of the present disclosure. In addition, all configurations and operations described in the embodiments are not necessarily essential as configurations and operations of the present disclosure. Here, the same components are denoted by the same reference signs, and any redundant description thereof is omitted.

### 1. Terms

A “real-time system” is an operating system (RTOS: RealTime OS) or a PLD (Programmable Logic Device) having functions and properties for executing time-constrained processing. The real-time system is often used for controlling an embedded system of industrial equipment or a transportation machine.

A “non-real-time OS” is a non-critical OS (Operating System) with a margin in processing time, and is also referred to as a GPOS (General Purpose Operating System). The non-real-time OS is generally rich in functionality, flexible, and relatively inexpensive to construct.

### 2. Description of Laser Apparatus According to Comparative Example

### 2.1 Configuration

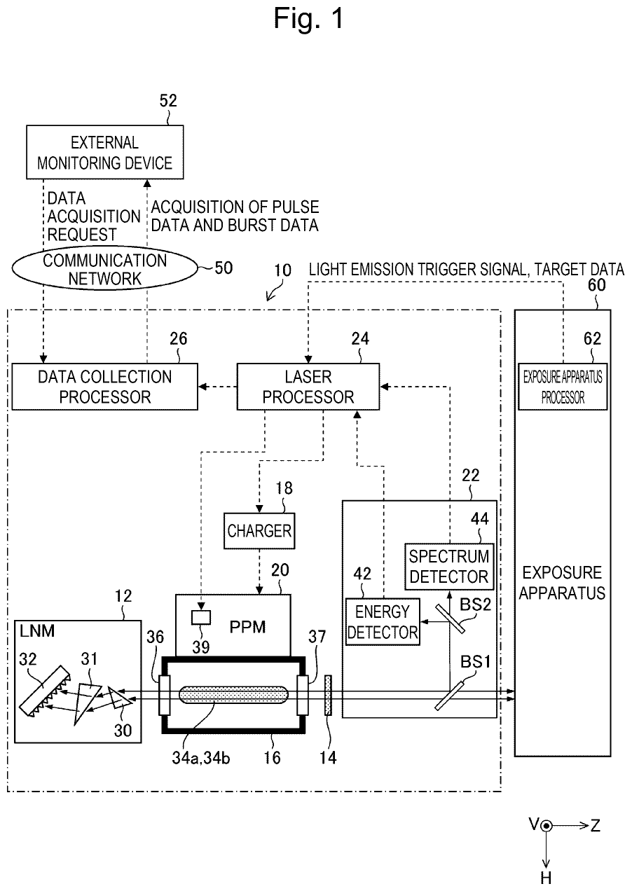

FIG. 1 schematically illustrates a configuration of a laser apparatus 10 according to a comparative example. The comparative example of the present disclosure is an example recognized by the applicant as known only by the applicant, and is not a publicly known example admitted by the applicant. The laser apparatus 10 includes an LNM 12, an output coupler (OC) 14, a chamber 16, a charger 18, a pulse power module (PPM) 20, a monitor module 22, a laser processor 24, and a data collection processor 26.

The LNM 12 includes prisms 30 and 31 and a grating 32. The prisms 30 and 31 are disposed such that a beam output from the chamber 16 is expanded and the expanded beam is incident on the grating 32 at a predetermined angle. A wavelength dispersion direction of the grating 32 is disposed to be perpendicular to a discharge direction between electrodes 34a and 34b in the chamber 16. The grating 32 is disposed in Littrow arrangement so that an incident angle and a diffracting angle of the beam are the same angle.

The OC 14 is a partial reflective mirror and is disposed to form an optical resonator with the LNM 12. A reflectance of the OC 14 may be, for example, 20% to 30%.

The chamber 16 is disposed on an optical path of the optical resonator, and includes a pair of the electrodes 34a and 34b and windows 36 and 37 through which a pulse laser beam is transmitted. The electrodes 34a and 34b are disposed facing each other in a direction perpendicular to a plane of FIG. 1. In FIG. 1, a direction perpendicular to the plane of the figure is referred to as a V direction. Further, a traveling direction of the pulse laser beam output from the OC 14 is defined as a Z direction, and a direction perpendicular to the Z direction and the V direction is defined as an H direction.

The chamber 16 is filled with excimer laser gas. The excimer laser gas includes, for example, a rare gas, a halogen gas, and a buffer gas. The rare gas may be an Ar or Kr gas. The halogen gas may be a F₂ gas. The buffer gas may be a Ne gas.

The charger 18 is electrically connected to charge an unillustrated charging capacitor in the PPM 20. The PPM 20 includes a switch 39 and the unillustrated charging capacitor, and is connected with the electrode 34a via an unillustrated feedthrough. The electrode 34b is connected to the grounded chamber 16.

The monitor module 22 includes a beam splitter BS1, a beam splitter BS2, an energy detector 42, and a spectrum detector 44. The beam splitter BS1 is disposed on an optical path of the pulse laser beam output from the OC 14, and is disposed such that the pulse laser beam reflected by the beam splitter BS1 enters the beam splitter BS2.

The beam splitter BS2 is disposed such that the pulse laser beam reflected by the beam splitter BS2 enters the energy detector 42, and the pulse laser beam transmitted through the beam splitter BS2 enters the spectrum detector 44.

The energy detector 42 includes a light condensing lens and a photosensor that are not illustrated. The photosensor may be a photodiode that is excellent in high-speed responsiveness and is resistant to ultraviolet light. The spectrum detector 44 may be a spectrometer including an unillustrated etalon and an image sensor that measures interference fringes generated in the etalon.

The laser processor 24 is a processing device including a CPU (Central Processing Unit), a main storage device, and an auxiliary storage device. The laser processor 24 is a real-time system. The laser processor 24 functions as a main control system of the laser apparatus 10.

The data collection processor 26 is a processing device including a CPU, a main storage device, and an auxiliary storage device. An OS of the data collection processor 26 is a non-real-time OS. The data collection processor 26 executes processing of collecting data such as pulse data related to a pulse laser beam output from the laser apparatus 10 and burst data generated in burst units of burst oscillation. The data collection processor 26 is connected to an external monitoring device 52 via a communication network 50.

The external monitoring device 52 includes a CPU, a main storage device, an auxiliary storage device, a display device such as a liquid crystal display (LCD) or an organic electroluminescence (EL) display, and an input device such as a keyboard or a voice input device. The external monitoring device 52 acquires the data collected by the data collection processor 26, and executes processing such as monitoring of an operation of the laser apparatus 10, information presentation of various kinds of data, data analysis, and presentation of analysis information.

The external monitoring device 52 may be connected to an unillustrated central management system via the communication network 50, or may transmit data from the external monitoring device 52 to the central management system. The external monitoring device 52 may be connected not only to the laser apparatus 10 but also to a plurality of laser apparatuses including other laser apparatuses not illustrated in FIG. 1.

The communication network 50 can transmit information in a wired manner, a wireless manner, or a combination thereof. The communication network 50 may be a wide area network or a local area network.

The laser apparatus 10 is connected to a laser irradiation device such as an exposure apparatus 60 or an unillustrated laser machining device. FIG. 1 illustrates the exposure apparatus 60. In this case, the laser processor 24 is connected to an exposure apparatus processor 62 of the exposure apparatus 60. The exposure apparatus processor 62 is a processing device including a CPU, a main storage device, and an auxiliary storage device, and controls the operation of the exposure apparatus 60.

### 2.2 Operation

The laser processor 24 receives a light emission trigger signal and target data such as target pulse energy and a target spectral linewidth from the laser irradiation device such as the exposure apparatus 60 or the laser machining device. The laser processor 24 sets a charging voltage of the charger 18 such that pulse energy of the pulse laser beam output from the laser apparatus 10 becomes the target pulse energy.

Then, the laser processor 24 transmits the light emission trigger signal to the PPM 20. The switch 39 in the PPM 20 is turned ON in synchronization with the light emission trigger signal, and a charge of the charging capacitor charged by a charging voltage Vhv is transferred to the electrode 34a via the unillustrated feedthrough or the like.

When discharge occurs between the electrode 34a and the electrode 34b in the chamber 16, the laser gas is excited, and a pulse laser beam of an ultraviolet wavelength having a wavelength of 150 nm to 380 nm, which is band-narrowed by the optical resonator formed of the OC 14 and the LNM 12, is output from the OC 14.

The pulse laser beam output from the OC 14 enters the monitor module 22. Then, the pulse energy of the pulse laser beam is detected by the energy detector 42. Further, a spectral linewidth and the like of the pulse laser beam are detected by the spectrum detector 44. The data detected by each of the energy detector 42 and the spectrum detector 44 is transmitted to the laser processor 24. The laser processor 24 receives the light emission trigger signal and the target data from the exposure apparatus 60 in a real-time state, and transmits the data such as the pulse energy to the data collection processor 26.

The pulse laser beam transmitted through the monitor module 22 enters the exposure apparatus 60.

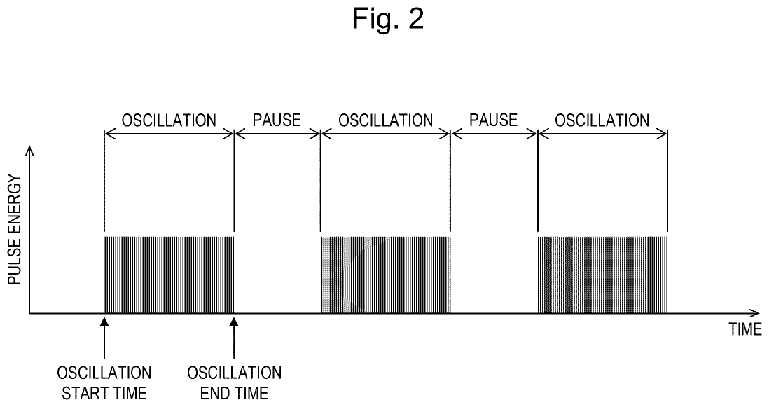

FIG. 2 illustrates an example of the burst oscillation by the laser apparatus 10. As illustrated in FIG. 2, the laser apparatus 10 performs the burst oscillation in which an oscillation period and a pause period are repeated. The oscillation period is a period in which pulse laser beam is continuously oscillated. The pause period is a period in which the oscillation is paused. Note that lengths of the oscillation period and the pause period need not be fixed.

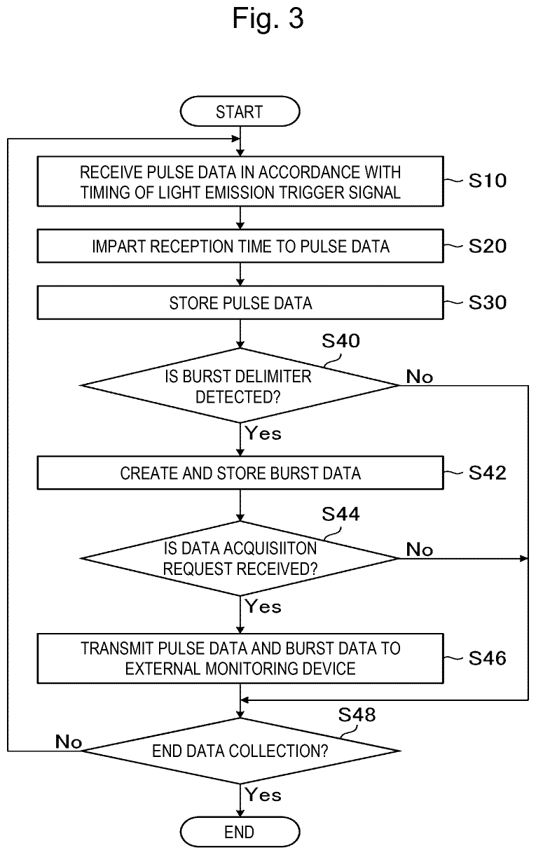

FIG. 3 is a flowchart illustrating an example of a processing procedure of the data collection processor 26 according to the comparative example. In step S10, the data collection processor 26 receives the pulse data from the laser processor 24 in accordance with a timing of the light emission trigger signal. The pulse data received by the data collection processor 26 includes at least one of the pulse energy, the wavelength, and the spectral linewidth.

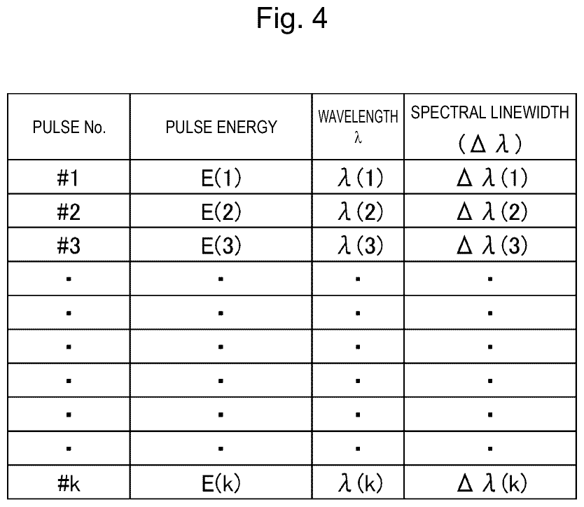

FIG. 4 illustrates an example of the pulse data received by the data collection processor 26. The data collection processor 26 receives the pulse data including the pulse energy, the wavelength, and the spectral linewidth for each pulse. Note that a pulse number (pulse No.) illustrated in FIG. 4 represents a number within the oscillation period.

In step S20 in FIG. 3, the data collection processor 26 imparts a reception time to the received pulse data. At this time, the reception time imparted to the pulse data is imparted in the non-real-time OS.

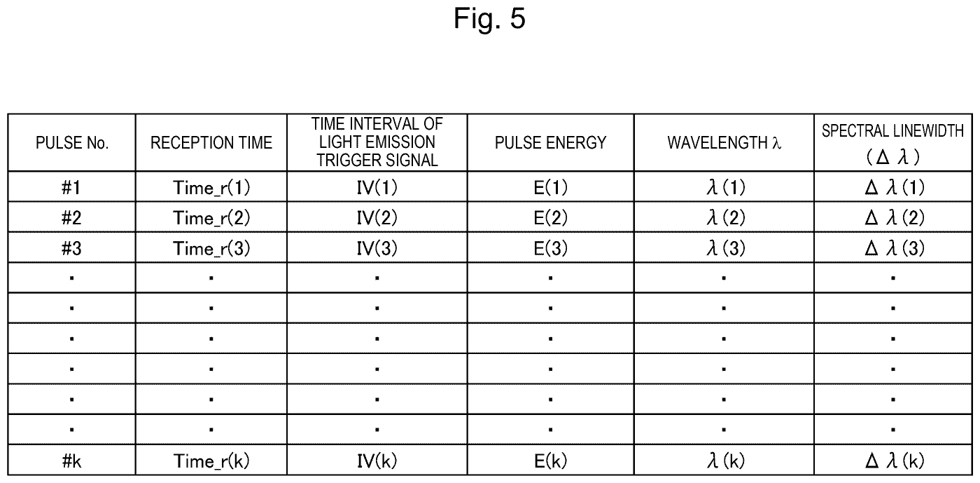

Thereafter, in step S30, the data collection processor 26 stores the pulsed data along with the imparted time. FIG. 5 illustrates an example of the pulse data stored by the data collection processor 26. The data collection processor 26 stores the reception time of the pulse data and the pulse data in association with each other for each pulse of the burst oscillation. For each oscillation period of the burst oscillation, the pulse data as illustrated in FIG. 5 is stored.

In step S40, the data collection processor 26 determines whether a burst delimiter is detected. The burst delimiter is, for example, when the pulse number (pulse No.) included in the pulse data is “1”. This is because the pulse number of each burst starts with “1”. That is, the pulse number “1” means it is a first pulse at an oscillation start of each burst. Therefore, the data collection processor 26 determines the burst delimiter when the pulse data having the pulse number 1 is received.

If a determination result in step S40 is Yes determination, that is, if the data collection processor 26 detects the burst delimiter, the data collection processor 26 proceeds to step S42.

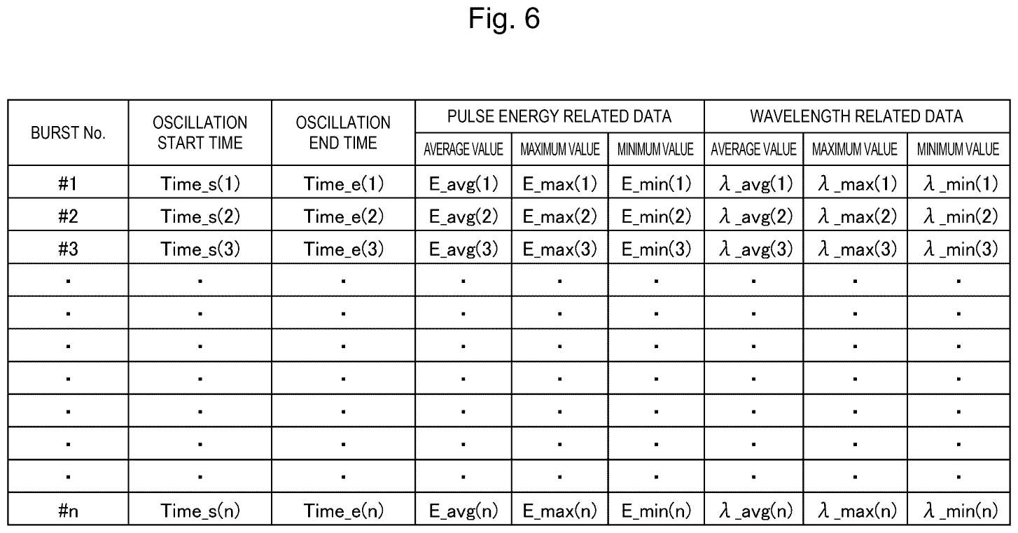

In step S42, the data collection processor 26 computes an oscillation start time and an oscillation end time of the burst oscillation, an average value, a maximum value, and a minimum value of the pulse energy, an average value, a maximum value, and a minimum value of the wavelength, and the like, from the pulse data in the burst with a lump of a pulse group in the oscillation period by the burst oscillation as a unit, creates burst data including these data, and stores the burst data in the auxiliary storage device in association with the burst number (burst No.). FIG. 6 illustrates an example of the burst data.

The oscillation start time may be a time imparted to the pulse data having the pulse number “1” which is the first pulse in the burst. The oscillation end time may be a time imparted to the pulse data of a last pulse in the burst. The data collection processor 26 may be configured to create and store the burst data including at least one of two or more pieces of data illustrated in FIG. 6. In addition, the data collection processor 26 may create not only the burst data illustrated in FIG. 6 but also the burst data including dispersion of the pulse energy, dispersion of the wavelength, an average value, a maximum value, a minimum value, and dispersion of the spectral linewidth, and the like.

In step S44, the data collection processor 26 determines whether or not a data acquisition request is received from the external monitoring device 52.

If a determination result in step S44 is Yes determination, that is, if the data collection processor 26 receives the data acquisition request from the external monitoring device 52, the data collection processor 26 proceeds to step S46.

In step S46, the data collection processor 26 transmits the pulse data and the burst data to the external monitoring device 52.

After step S46, the processing proceeds to step S48.

If the determination result in step S40 is No determination, that is, if the data collection processor 26 does not detect the burst delimiter, the data collection processor 26 skips steps S42 to S46, and proceeds to step S48.

If the determination result in step S44 is No determination, that is, if the data collection processor 26 does not receive the data acquisition request from the external monitoring device 52, the data collection processor 26 skips step S46 and proceeds to step S48.

In step S48, the data collection processor 26 determines whether or not to end data collection. If a determination result in step S48 is No determination, that is, if the data collection processor 26 does not end the data collection, the data collection processor 26 returns to step S10 and repeats the processing of step S10 to step S48 until the data collection is ended.

If the determination result in step S48 is Yes determination, that is, if the data collection processor 26 ends the data collection, the flowchart in FIG. 3 ends.

The external monitoring device 52 transmits the data acquisition request to the data collection processor 26 to acquire and store the pulse data and the burst data from the data collection processor 26 at an arbitrary timing.

The external monitoring device 52 displays the data acquired from the data collection processor 26 on the display device or analyses the data.

### 2.3 Problem

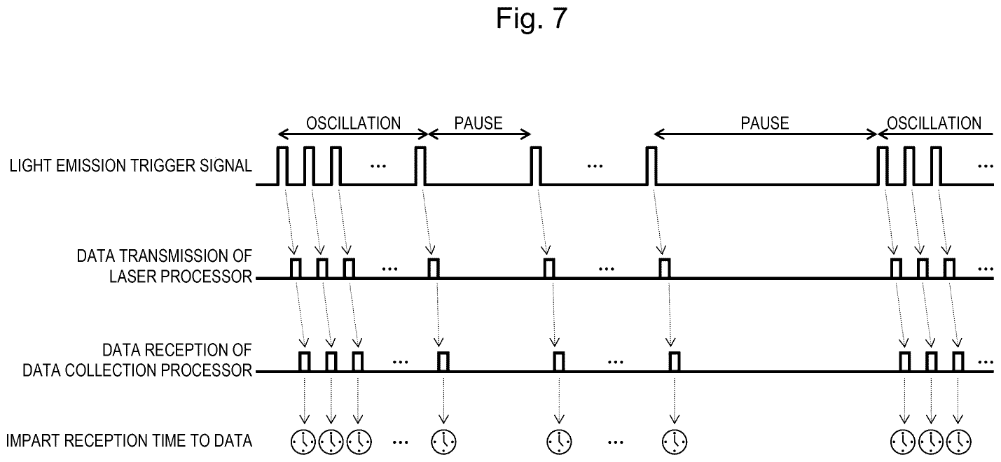

FIG. 7 illustrates a timing chart of transmission and reception of the pulse data in the laser apparatus 10 according to the comparative example. The laser processor 24 transmits the pulse data of each pulse laser beam oscillated in response to the light emission trigger signal to the data collection processor 26 at a timing synchronized with the light emission trigger signal.

The data collection processor 26 imparts the reception time to the data received from the laser processor 24 for each pulse. At this time, since the OS of the data collection processor 26 is a non-real-time OS and a delay is generated in the time imparted in accordance with the processing performed when the pulse data is received, accuracy of the time imparted for each pulse may be insufficient. An object of the present disclosure is to impart a time close to a timing of the light emission trigger signal to each pulse data in a non-real-time OS.

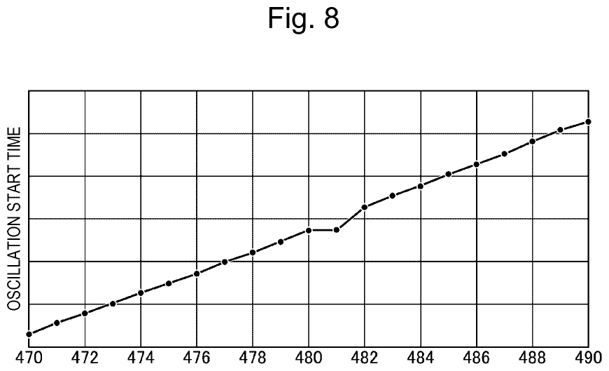

FIG. 8 illustrates the oscillation start time of each of bursts No. 470 to 490. Note that the oscillation period and the pause period of each burst illustrated in FIG. 8 are fixed, respectively. However, in a graph in FIG. 8, a line connecting the oscillation start times of the burst numbers is not a straight line. This is because a delay is generated in the time (reception time) imparted to the pulse data.

In an example in FIG. 8, the oscillation start times of the burst No. 480 and the burst No. 481 are the same. In this case, when determination is made with the oscillation start times, there is a possibility of mistaking an order of the bursts. This mistake affects data analysis performed in the external monitoring device 52. For example, when an exposure result in the exposure apparatus 60 is analyzed, the analysis is performed with the data of the pulse laser beam different from the pulse laser beam used for exposure.

### 3. Embodiment 1

### 3.1 Configuration

A configuration of a laser apparatus according to Embodiment 1 may be similar to the configuration of the laser apparatus 10 described with reference to FIG. 1.

### 3.2 Operation

In the laser apparatus according to Embodiment 1, contents of the processing executed by the data collection processor 26 are different from that of the processing in the comparative example (FIG. 3).

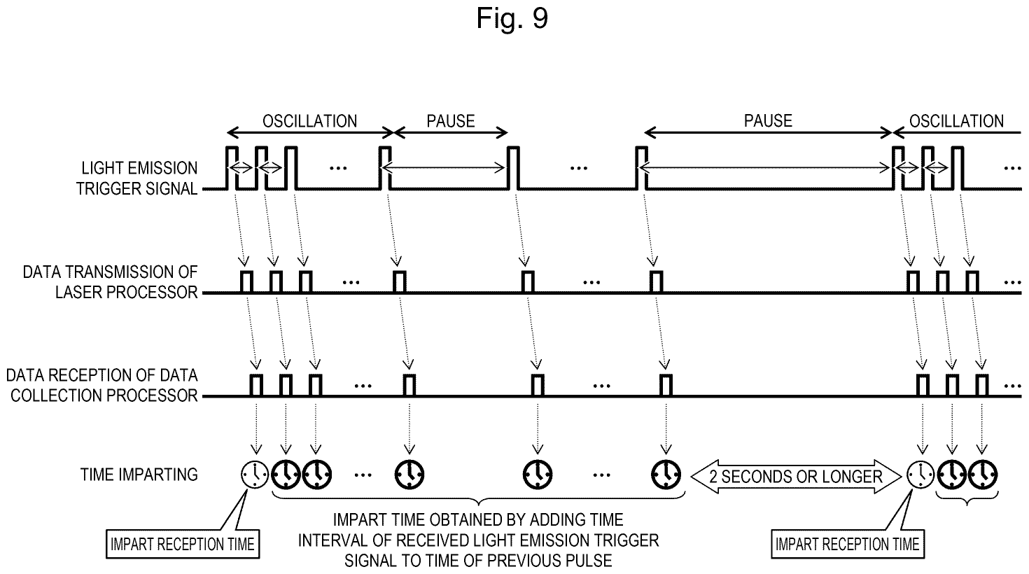

FIG. 9 illustrates a timing chart of transmission and reception of pulse data in the laser apparatus according to Embodiment 1. The laser processor 24 receives the light emission trigger signal from the exposure apparatus 60 and measures a time interval of the light emission trigger signal. The time interval of the light emission trigger signal may be referred to as a “light emission trigger signal interval”. Since the laser processor 24 is a real-time system, a measurement error of the measured light emission trigger signal interval is a small value. The data collection processor 26 receives, from the laser processor 24, the pulse data including data of the light emission trigger signal interval in accordance with the timing of the light emission trigger signal. The data collection processor 26 receives the pulse data for each pulse.

The laser processor 24 is an example of a “first processor” in the present disclosure. The data collection processor 26 is an example of a “second processor” in the present disclosure. Each of the laser processor 24 and the data collection processor 26 is specially configured or programmed to execute various kinds of processing included in the present disclosure.

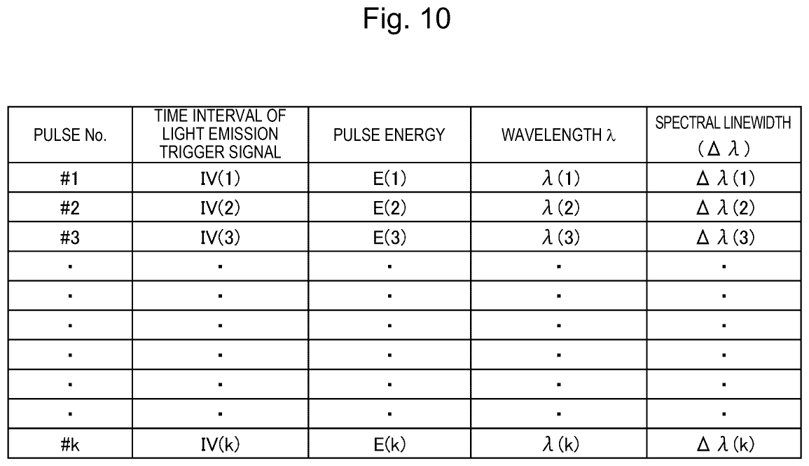

FIG. 10 illustrates an example of the pulse data received by the data collection processor 26 according to Embodiment 1. The data collection processor 26 receives the time interval of the light emission trigger signal, the pulse energy, the wavelength, and the spectral linewidth for each pulse number corresponding to the light emission trigger signal.

The data collection processor 26 compares the light emission trigger signal interval included in the pulse data with a predetermined set value, and determines whether or not the light emission trigger signal interval is equal to or larger than the set value. The data collection processor 26 imparts the reception time to the pulse data when the light emission trigger signal interval included in the pulse data is equal to or larger than the set value. This reception time is imparted by the non-real-time OS.

In addition, when the time interval of the light emission trigger signal included in the received pulse data is not equal to or larger than the set value, the data collection processor 26 imparts, to the pulse data, a time obtained by adding the time interval of the light emission trigger signal to the time of the previous (immediately preceding) pulse data. The set value is larger than the delay in the time imparted by the non-real-time OS. The set value ranges from 2 seconds to 85 seconds, for example.

That is, when the time interval of the light emission trigger signal is smaller than the set value, the data collection processor 26 imparts the time obtained by adding the received time interval to the time imparted to the pulse data of the pulse laser beam corresponding to the previous light emission trigger signal to the received pulse data (see FIG. 9).

For example, the light emission trigger signal received prior to (immediately before) a first light emission trigger signal from the left (leftmost) in the burst oscillation illustrated in FIG. 9 is the light emission trigger signal corresponding to the last pulse in the oscillation period immediately before the pause period (for example, the pause period of 2 seconds or longer) not illustrated in FIG. 9.

In that case, when the data collection processor 26 receives the pulse data of the pulse laser beam output in response to the first light emission trigger signal from the left of FIG. 9, since the time interval between the first light emission trigger signal from the left and the previous light emission trigger signal is equal to or larger than the set value, the data collection processor 26 imparts the reception time of the pulse data by the non-real-time OS to the pulse data of the pulse laser beam corresponding to the first light emission trigger signal from the left. In this case, the first light emission trigger signal from the left is an example of a “first light emission trigger signal” in the present disclosure, and the unillustrated previous light emission trigger signal is an example of a “second light emission trigger signal” in the present disclosure.

Next, when the data collection processor 26 receives the pulse data of the pulse laser beam output in response to the second light emission trigger signal from the left of FIG. 9, since the time interval between the second light emission trigger signal from the left and the first light emission trigger signal from the left is smaller than the set value, the data collection processor 26 imparts a time obtained by adding the time interval to the time of the pulse data received immediately before. In this case, the second light emission trigger signal from the left is an example of the “first light emission trigger signal” in the present disclosure, and the first light emission trigger signal from the left is an example of the “second light emission trigger signal” in the present disclosure. Thereafter, similarly for the pulse data corresponding to each pulse in the oscillation period of the burst oscillation, a time obtained by adding the time interval of the light emission trigger signal to the time of the previous pulse data is imparted.

The set value may be determined in consideration of a time required for switching a wafer to be exposed. It is preferable to determine the set value of the wafer so as to avoid the time being imparted by the non-real-time OS during a processing period of exposing the same wafer. For example, in a typical semiconductor manufacturing process, the time interval of the light emission trigger signal when the same wafer is exposed is smaller than 2 seconds. Therefore, by setting the set value to 2 seconds, the reception time can be imparted to the pulse data by the non-real-time OS at a timing of changing the wafer to be exposed.

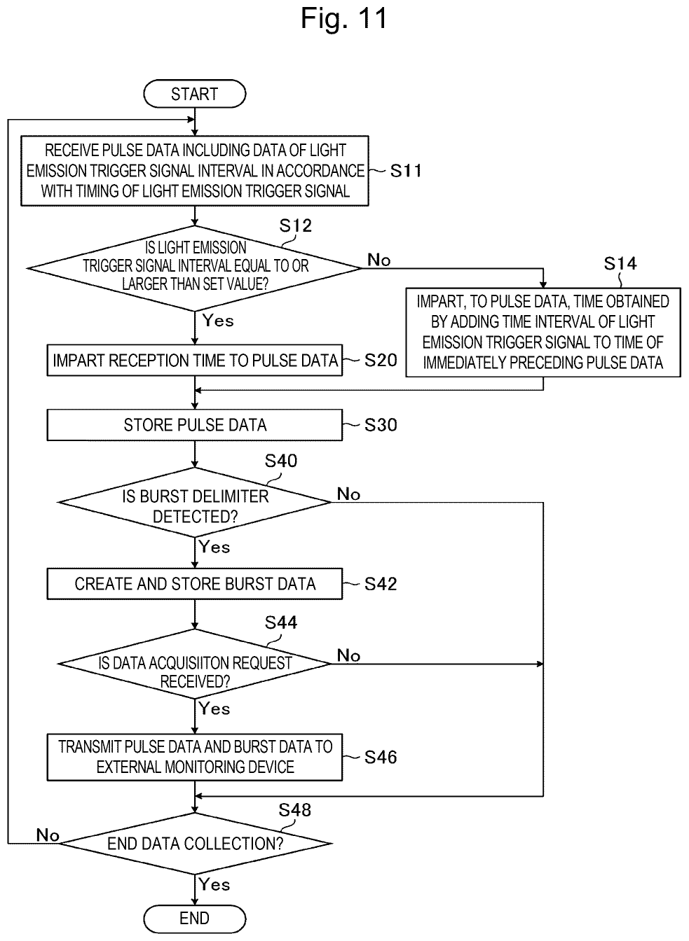

FIG. 11 is a flowchart illustrating an example of a processing procedure of the data collection processor 26 according to Embodiment 1. With respect to FIG. 11, differences from the flowchart in FIG. 3 will be described. The flowchart illustrated in FIG. 11 includes step S11 instead of step S10 in FIG. 3, and includes step S12 between step S11 and step S20. Further, the flowchart illustrated in FIG. 11 includes step S14 branching from determination processing in step S12.

In step S11, the data collection processor 26 receives the pulse data including the data of the light emission trigger signal interval from the laser processor 24 in accordance with the timing of the light emission trigger signal.

Thereafter, in step S12, the data collection processor 26 determines whether or not the light emission trigger signal interval is equal to or larger than the set value.

If a determination result in step S12 is Yes determination, that is, if the light emission trigger signal interval is equal to or larger than the set value, the data collection processor 26 proceeds to step S20.

If the determination result in step S12 is No determination, that is, if the light emission trigger signal interval is smaller than the set value, the data collection processor 26 proceeds to step S14.

In step S14, the data collection processor 26 imparts the time obtained by adding the time interval of the light emission trigger signal to the time of the immediately preceding pulse data to the pulse data. After step S14, the data collection processor 26 proceeds to step S30.

The other operations may be similar to those in FIG. 1.

Thus, instead of the “reception time” described in FIG. 5, the reception time or the time obtained by adding the time interval to the time of the previous pulse data is imparted. A time imparting method according to Embodiment 1 described in FIG. 10 and FIG. 11 is an example of a “time imparting method” in the present disclosure.

### 3.3 Effect and Advantage

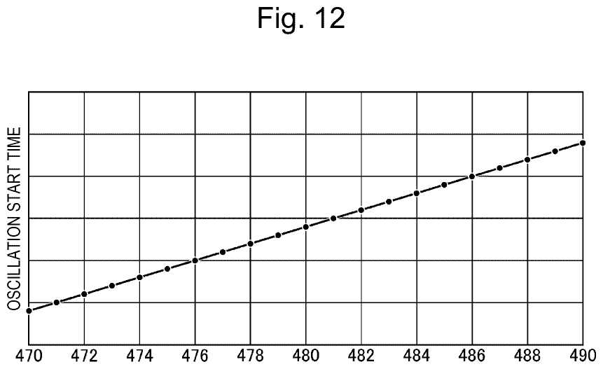

FIG. 12 illustrates the oscillation start time of each of the bursts No. 470 to 490 in the laser apparatus according to Embodiment 1. As illustrated in FIG. 12, a line connecting the oscillation start times of the burst numbers is a straight line. With such oscillation start times, the order of the bursts is not mistaken.

Further, in Embodiment 1, the data collection processor 26 imparts the reception time to the pulse data received from the laser processor 24 by the non-real-time OS when the time interval of the light emission trigger signal is equal to or larger than the set value, and when the time interval of the light emission trigger signal is larger than the delay in the time imparted by the non-real-time OS. Therefore, according to the time imparting method of Embodiment 1, the times imparted to two or more pieces of the pulse data do not become the same, and the order of the bursts is not mistaken.

According to Embodiment 1, in the non-real-time OS which is a general-purpose OS, the time closer to the timing of the light emission trigger signal can be imparted to each pulse data. The data collection processor 26 that executes the time imparting method according to Embodiment 1 can impart an appropriate time to each pulse data of the pulse laser beam output in response to the light emission trigger signal, and can collect and accumulate more accurate logs as compared with the configuration of the comparative example. This contributes to enhancement of a monitoring function in the external monitoring device 52.

### 4. Embodiment 2

### 4.1 Configuration

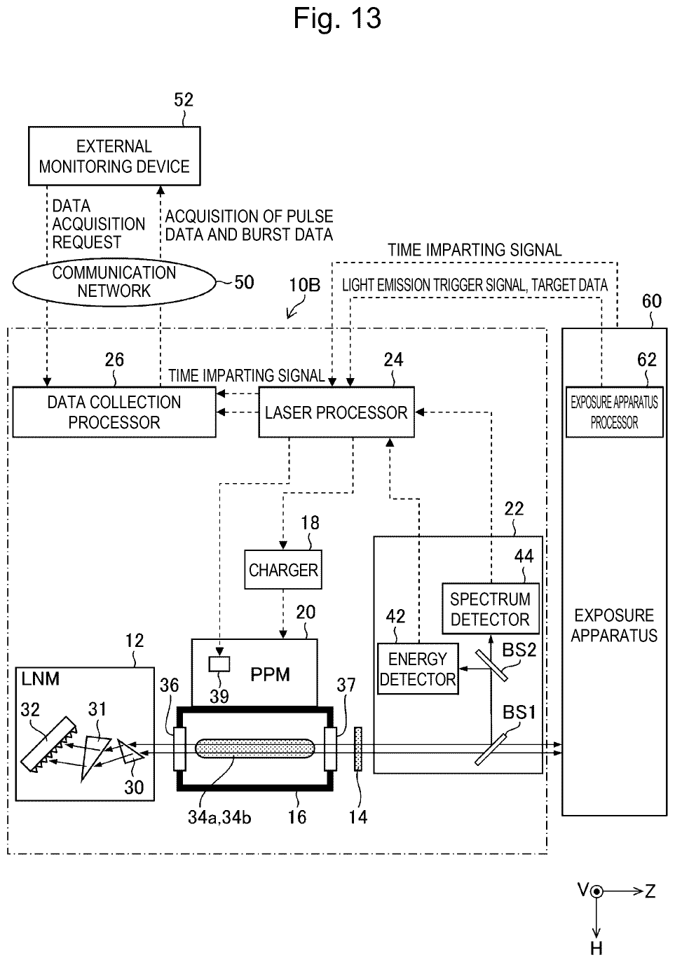

FIG. 13 schematically illustrates a configuration of a laser apparatus 10B according to Embodiment 2. With respect to FIG. 13, differences from the configuration illustrated in FIG. 1 will be described.

The laser apparatus 10B according to Embodiment 2 differs from Embodiment 1 in that a time imparting request is transmitted to the laser apparatus 10B from the laser irradiation device such as the exposure apparatus 60 or the laser machining device. FIG. 13 illustrates a transmission path of a signal of the time imparting request transmitted from the exposure apparatus 60 to the data collection processor 26 via the laser processor 24. The signal of the time imparting request is referred to as a time imparting signal. The other configurations may be similar to those in FIG. 1.

### 4.2 Operation

The time imparting signal is a signal sent when it is desired to reacquire the time based on the non-real-time OS. The data collection processor 26 receives the time imparting signal from the exposure apparatus 60 or the laser processor 24, and imparts the time of the non-real-time OS to the pulse data in response to the received time imparting request. When the time imparting signal is not received, the data collection processor 26 imparts an accurate time to each pulse data by adding the time interval of the light emission trigger signal to the time of the pulse data related to the previous reception.

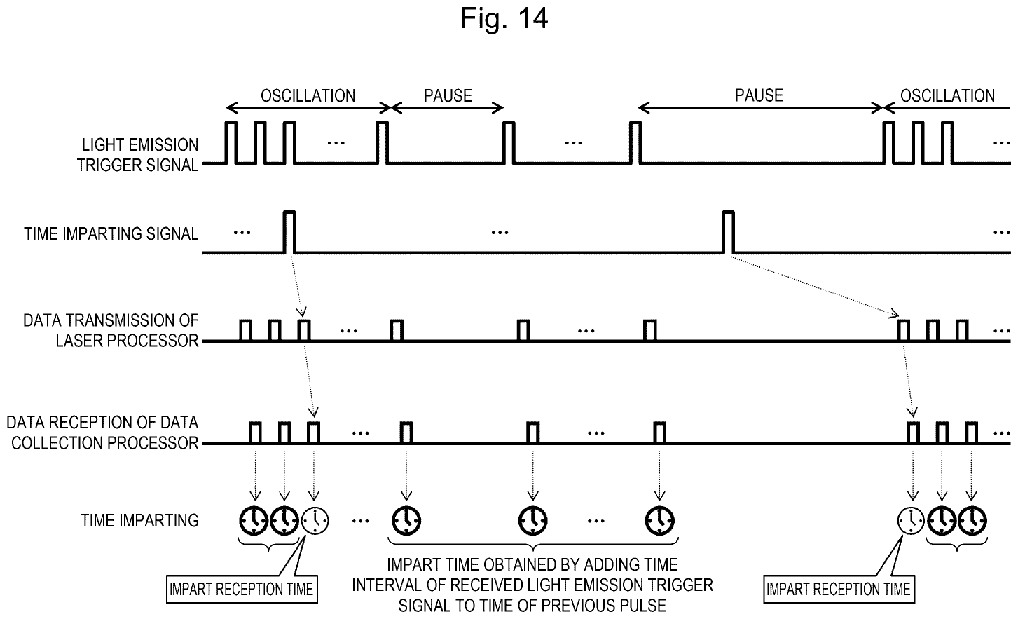

FIG. 14 is a timing chart of transmission and reception of the pulse data in the laser apparatus 10B according to Embodiment 2. With respect to FIG. 14, differences from Embodiment 1 described with reference to FIG. 9 will be described. While the time interval of the light emission trigger signal and the set value are compared and the time of the non-real-time OS is automatically imparted when the time equal to or longer than the set value has elapsed in Embodiment 1, Embodiment 2 differs from Embodiment 1 in that the time of the non-real-time OS is imparted in response to the reception of the time imparting signal.

FIG. 14 illustrates an example of a case where the time imparting signal is received during the burst oscillation period and a case where the time imparting signal is received during the pause period. When the time imparting signal is received and the reception time is imparted to the data in a case where the time interval of the light emission trigger signal is short, such as during the burst oscillation, the delay is generated in the time to be imparted, however, the same time as the previous data is less likely to be imparted.

In addition, in the case where the time interval of the light emission trigger signal is short, such as during the burst oscillation, an error may be returned and the time imparting request may not be accepted. The case where the time interval of the light emission trigger signal is short may be, for example, a case where the time interval is 2 seconds or shorter.

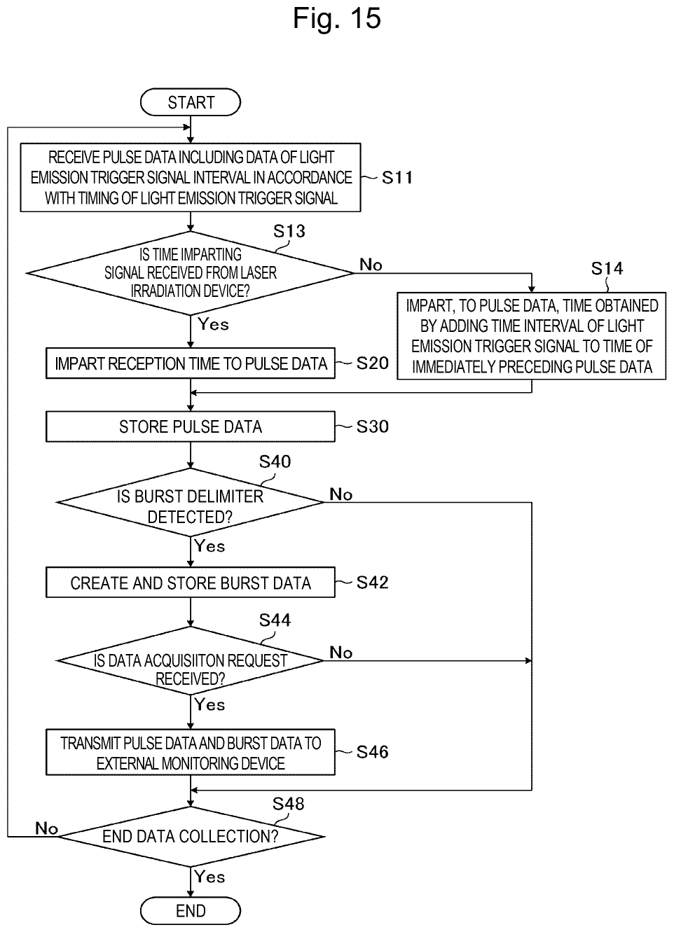

FIG. 15 is a flowchart illustrating an example of a processing procedure of the data collection processor 26 according to Embodiment 2. With respect to FIG. 15, differences from the flowchart in FIG. 11 will be described. The flowchart illustrated in FIG. 15 includes step S13 instead of step S12 in FIG. 11.

In step S13, the data collection processor 26 determines whether or not the time imparting signal is received from the laser irradiation device. The exposure apparatus 60 is an example of the laser irradiation device. The laser irradiation device is not limited to the exposure apparatus 60, and may be a laser machining device.

If a determination result in step S13 is Yes determination, that is, if the data collection processor 26 receives the time imparting signal, the data collection processor 26 proceeds to step S20. In step S20, the data collection processor 26 imparts the reception time to the pulse data received next. The data collection processor 26 may receive the time imparting signal at a timing of the burst delimiter.

If the determination result in step S13 is No determination, that is, if the data collection processor 26 does not receive the time imparting signal, the data collection processor 26 proceeds to step S14.

The other operations are similar to those of the flowchart in FIG. 11.

### 4.3 Effect and Advantage

According to Embodiment 2, same advantages as those of Embodiment 1 can be obtained. Further, according to Embodiment 2, by imparting the time of the non-real-time OS to the pulse data by designation from the laser irradiation device such as the exposure apparatus 60, a real-time accurate time can be imparted within an arbitrary range of the light emission instruction from the laser irradiation device.

### 5. Others

The description above is intended to be illustrative and the present disclosure is not limited thereto. Therefore, it would be obvious to those skilled in the art that various modifications to the embodiments of the present disclosure would be possible without departing from the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A time imparting method for imparting a time to two or more pieces of pulse data of a laser apparatus that burst-oscillates a pulse laser beam, the time imparting method comprising:
causing a first processor including a real-time system to receive a first light emission trigger signal from a laser irradiation device and to measure a time interval between a second light emission trigger signal received immediately before the first light emission trigger signal and the first light emission trigger signal in the real-time system; and
causing a second processor to receive the time interval from the first processor, and when the time interval is smaller than a set value, to impart a time obtained by adding the time interval to a time imparted to pulse data of a pulse laser beam corresponding to the second light emission trigger signal, to pulse data of a pulse laser beam corresponding to the first light emission trigger signal.

2. The time imparting method according to claim 1, wherein
the second processor acquires the pulse data for each pulse.

3. The time imparting method according to claim 1, wherein
the pulse data includes at least one of pulse energy, a wavelength, and a spectral linewidth.

4. The time imparting method according to claim 1, wherein
the second processor receives the pulse data from the first processor.

5. The time imparting method according to claim 1, wherein
the second processor includes a non-real-time OS,
the second processor receives the pulse data of the pulse laser beam corresponding to the first light emission trigger signal from the first processor, and when the time interval is equal to or larger than the set value, the non-real-time OS imparts a time at which the pulse data is received to the pulse data of the pulse laser beam corresponding to the first light emission trigger signal.

6. The time imparting method according to claim 1, wherein
the set value ranges from 2 seconds to 85 seconds.

7. The time imparting method according to claim 1, wherein
the laser irradiation device is an exposure apparatus or a laser machining device.

8. The time imparting method according to claim 1, wherein
when a burst delimiter of the burst oscillation is detected, the second processor creates burst data including at least one of an oscillation start time and an oscillation end time of the burst oscillation, an average value, a maximum value, and a minimum value of pulse energy, and an average value, a maximum value, and a minimum value of a wavelength from pulse data of a pulse group in an oscillation period of the burst oscillation.

9. A time imparting method for imparting a time to two or more pieces of pulse data of a laser apparatus that burst-oscillates a pulse laser beam, the time imparting method comprising:
causing a first processor including a real-time system to receive a first light emission trigger signal from a laser irradiation device and to measure a time interval between a second light emission trigger signal received immediately before the first light emission trigger signal and the first light emission trigger signal in the real-time system; and
causing a second processor to receive the time interval from the first processor, and when a time imparting signal is not received from the laser irradiation device, to impart a time obtained by adding the time interval to a time of pulse data of a pulse laser beam corresponding to the second light emission trigger signal, to pulse data of a pulse laser beam corresponding to the first light emission trigger signal.

10. The time imparting method according to claim 9, wherein
the second processor acquires the pulse data for each pulse.

11. The imparting method according to claim 9, wherein
the pulse data includes at least one of pulse energy, a wavelength, and a spectral linewidth.

12. The time imparting method according to claim 9, wherein
the second processor receives the pulse data from the first processor.

13. The time imparting method according to claim 9, wherein
the second processor includes a non-real-time OS,
the second processor receives the pulse data of the pulse laser beam corresponding to the first light emission trigger signal from the first processor, and when the time imparting signal is received, the non-real-time OS imparts a time at which the pulse data is received to the pulse data of the pulse laser beam corresponding to the first light emission trigger signal.

14. The time imparting method according to claim 9, wherein
the laser irradiation device is an exposure apparatus or a laser machining device.

15. A laser apparatus that outputs a pulse laser beam in response to a light emission trigger signal received from a laser irradiation device, the laser apparatus comprising:
a first processor including a real-time system and configured to receive a first light emission trigger signal from the laser irradiation device and to measure a time interval between a second light emission trigger signal received immediately before the first light emission trigger signal and the first light emission trigger signal in the real-time system; and
a second processor configured to receive the time interval from the first processor and, when the time interval is smaller than a set value, to impart a time obtained by adding the time interval to a time of pulse data of a pulse laser beam corresponding to the second light emission trigger signal, to pulse data of a pulse laser beam corresponding to the first light emission trigger signal.

16. The laser apparatus according to claim 15, wherein
the second processor acquires the pulse data for each pulse.

17. The laser apparatus according to claim 15, wherein
the pulse data includes at least one of pulse energy, a wavelength, and a spectral linewidth.

18. The laser apparatus according to claim 15, wherein
the second processor includes a non-real-time OS,
the second processor receives the pulse data of the pulse laser beam corresponding to the first light emission trigger signal from the first processor, and when the time interval is equal to or larger than the set value, the non-real-time OS imparts a time at which the pulse data is received to the pulse data of the pulse laser beam corresponding to the first light emission trigger signal.

19. The laser apparatus according to claim 15, wherein
the set value ranges from 2 seconds to 85 seconds.

20. The laser apparatus according to claim 15, wherein
the laser irradiation device is an exposure apparatus or a laser machining device.
